(19) United States
(12) Patent Application Publication
(10) Pub. No.: US 2019/0033389 A1
(43) Pub. Date: Jan. 31, 2019

(54) Aging Of An Electrochemical Storage Means

(71) Applicant: SIEMENS AKTIENGESELLSCHAFT, Muenchen (DE)

(72) Inventors: Holger WOLFSCHMIDT, Erlangen (DE); Christopher BETZIN, Forchheim (DE)

(73) Assignee: Siemens Aktiengesellschaft, Muenchen (DE)

(21) Appl. No.: 16/075,809

(22) PCT Filed: Dec. 6, 2016
(86) PCT No.: PCT/EP2016/079832

§ 371 Date: Aug. 6, 2018

(30) Foreign Application Priority Data
Feb. 4, 2016 (DE) 10 2016 201 710.1
Nov. 24, 2016 (DE) 10 2016 223 326.2

(51) Int. Cl. G01R 31/36; H01M 10/48

(52) U.S. Cl. CPC G01R 31/3679; H01M 10/48; G01R 31/3662; G01R 31/3624

(57) ABSTRACT

Various embodiments of the present disclosure may include a method for determining the age of an electrochemical storage means. Some examples include a method comprising: recording a first voltammogram using a cyclic voltammetry process at a first time; recording a second voltammogram at a second time; identifying a first extreme value in the first voltammogram and a second extreme in the second, with a voltage and a current intensity associated with each extreme value; and determining the age of the electrochemical storage means based at least in part on a difference between the first and second extreme value.

### CROSS-REFERENCE TO RELATED APPLICATIONS

This application is a U.S. National Stage Application of International Application No. PCT/EP2016/079832 filed Dec. 6, 2016, which designates the United States of America, and claims priority to DE Application No. 10 2016 201 710.1 filed Feb. 4, 2016 and DE Application No. 10 2016 223 326.2 filed Nov. 24, 2016, the contents of which are hereby incorporated by reference in their entirety.

### TECHNICAL FIELD

The present disclosure relates to electrochemical storage. Various embodiments may include a method for determining the aging or the age of an electrochemical storage means, in particular a lithium-ion cell.

### BACKGROUND

Electrochemical storage means, in particular lithium-ion cells, require a long lifetime for economic operation. In general, the electrochemical storage means should be able to ensure both a low calendric aging and a high number of cycles. EP 2389703 A1 proposes the recording of an impedance spectrum to determine the aging of a battery cell.

In EP 1450173 A2, the aging of an electrochemical storage means is determined by means of full charge and discharge cycles. However, the electrochemical storage means has to be decoupled from its provided operation for this purpose.

### SUMMARY

The teachings of the present disclosure include an improved method for determining the aging of an electrochemical storage means. For example, some embodiments include a method for determining the aging SOH of an electrochemical storage means, comprising the following steps: identification of a first voltammogram (11, 12) by means of a cyclic voltammetry process at a first time; identification of a second voltammogram (21, 22) by means of a further cyclic voltammetry process at a second time that is later relative to the first time; identification of a first extreme value (41) in the first voltammogram (11, 12) and of a second extreme value (42) in the second voltammogram (21, 22), wherein at least one voltage U₁, U₂ and a current intensity I₁, I₂ are associated with each extreme value (41, 42); and determination of the aging SOH of the electrochemical storage means depending on a difference between the first and second extreme value (41, 42).

In some embodiments, the difference is formed by the numerical difference ΔU=U₁−U₂ of the voltages U₁, U₂ associated with the extreme values (41, 42).

In some embodiments, the aging SOH is determined by SOH=1−|ΔU|/U₀, wherein U₀ is in the range of from 10 mV to 50 mV.

In some embodiments, the difference is formed by the numerical difference ΔI=I₁−I₂ of the current intensities I₁, I₂ associated with the extreme values (41, 42).

In some embodiments, the aging SOH is determined by SOH=1−|ΔI|I₀, wherein I₀ is in the range of from 100 mA to 500 mA.

In some embodiments, a third extreme value (43) in the first voltammogram (11, 12) and a fourth extreme value (44) in the second voltammogram (21, 22) with respectively associated voltages U₃, U₄ and current intensities I₃, I₄ are identified, wherein the first and second extreme value (41, 42) are assigned to a redox reaction and the third and fourth extreme value (43, 44) are assigned to an oxidation reaction of the electrochemical energy storage means.

In some embodiments, the difference is formed by the numerical difference (I₁+|I₃|)−(I₂−|I₄|).

In some embodiments, the difference is formed by the numerical quotient [I₂/(I₂+I₄)]/[I₁(I₁+I₃)].

In some embodiments, the difference is formed by the numerical quotient (I₁−I₃)/(I₂−I₄).

In some embodiments, the difference is formed by the angle Δα (31) between a first and a second straight line (61, 62), wherein the first straight line (61) is set by the first and third extreme value (41, 43) and the second straight line (62) is set by the second and fourth extreme value (42, 44).

In some embodiments, the aging SOH is determined by SOH=1−|Δα|/α₀, wherein α₀ is in the range of from 5 degrees to 15 degrees.

In some embodiments, a lithium-ion cell is used as the electrochemical storage means.

In some embodiments, the first and/or second extreme value (41, 42) is set as a peak value of the current intensity in the range of from 3.4 V to 3.7 V.

In some embodiments, a value in the range of from 0.01 mV/s to 0.03 mV/s is used as the voltage scan rate of the first and/or second cyclic voltammetry process (21, 22).

In some embodiments, an energy storage means of an aircraft, in particular of an electric aircraft, is used as the electrochemical storage means.

### BRIEF DESCRIPTION OF THE DRAWINGS

Further advantages, features, and details of the teachings emerge from the exemplary embodiments described below and with reference to the drawings, in which, in schematized form:

FIG. 1 shows a first and second voltammogram of an electrochemical storage means, according to teachings of the present disclosure; and

FIG. 2 shows a further first and second voltammogram of an electrochemical storage means, according to teachings of the present disclosure.

Identical, equivalent, or identically acting elements may have the same reference symbols in the figures.

### DETAILED DESCRIPTION

In some embodiments, a method for determining the aging SOH of an electrochemical storage means comprises the following steps:
identification of a first voltammogram by means of a cyclic voltammetry process at a first time;
identification of a second voltammogram by means of a further cyclic voltammetry process at a second time that is later relative to the first time;
identification of a first extreme value in the first voltammogram and of a second extreme value in the second voltammogram, wherein at least one voltage U₁, U₂ and a current intensity I₁, I₂ are associated with each extreme value; and
determination of the aging SOH of the electrochemical storage means depending on a difference between the first and second extreme value.

In some embodiments, a method includes determining the aging of the electrochemical storage means by means of a comparison between the first and second voltammogram. The difference between the first and second extreme value is used for this purpose. In the course of aging of the electrochemical storage means, the voltammogram thereof changes from the first voltammogram to the second voltammogram. This change can be seen particularly clearly from the extreme values of the respective voltammogram, with the result that the difference of the extreme values is used for determining the aging.

In some embodiments, a method to determine the aging of the electrochemical storage means during the operation thereof includes recording the voltammograms in parallel with the mentioned operation, with the result that the electrochemical storage means is disturbed as little as possible. The identification of the voltammograms does not lead to further aging of the electrochemical storage means either. In some embodiments, the change in the extreme values (difference between the first and second extreme value) of the recorded voltammograms (first and second voltammogram) correlates to the aging of the electrochemical storage means.

In some embodiments, no full cycles, that is to say no charge and/or discharge cycles, are necessary for determining the aging. In particular, the electrochemical storage means or a system that comprises the electrochemical storage means does not have to be decoupled during the operation thereof according to the intended application for determining the aging of said electrochemical storage means. This is therefore the case since the extreme values can be identified directly from the voltammograms. Some embodiments include remotely accessing the aging state, that is to say the aging of the electrochemical storage means, without deploying, for example, service personnel at the location of the electrochemical storage means. The storage and evaluation of the extreme values also permits a forecast, which makes it possible to predict or to determine the aging of the electrochemical storage means in future operation.

The cyclic voltammetry process, which is used to examine electrochemical processes, may be carried out by means of a constant voltage scan rate. In this case, the electrochemical storage means is subjected to a constant voltage scan rate and the current response of said electrochemical storage means, that is to say the current intensity, is measured. As a result thereof, the electrochemical processes within the electrochemical storage means can be detected and characterized. Depending on the present electrochemical process, the detected or measured current intensity changes, with the result that said current intensity has characteristic features, for example extreme values (first and second extreme value). The characteristic features mentioned, that is to say the first and second extreme value, are dependent on aging, with the result that the aging of the electrochemical storage means can be determined in accordance with the invention from a comparison, that is to say from the identification of the difference between the first and second extreme value.

In some embodiments, the difference is formed by the numerical difference ΔU=U₁−U₂ of the voltages U₁, U₂ associated with the extreme values (41, 42). In other words, the shift of the extreme values in the voltammograms, that is to say the shift of the second extreme value with respect to the first extreme value, is used as a measure for the aging of the electrochemical storage means. In this case, the shift relates to the voltages associated with the extreme values. This may provide a particularly efficient method for determining the aging of the electrochemical storage means.

Some embodiments include determining the aging SOH by SOH=1−|ΔU|/U₀, wherein U₀ is in the range of from 10 mV to 50 mV. A value of U₀ of 30 mV may be used.

In some embodiments, the difference is formed by the numerical difference ΔI=I₁−I₂ of the current intensities I₁, I₂ associated with the extreme values. In other words, the change in the level of the extreme values from the first voltammogram to the second voltammogram is used for determining the aging. This makes it possible to determine the aging of the electrochemical storage means in a particularly efficient manner since the current intensity can be detected particularly precisely. In this case, it may determine the aging SOH by SOH=1−|ΔI|/I₀, wherein I₀ is in the range of from 100 mA to 500 mA. In some embodiments, a value of I₀ of 400 mA may be used.

In some embodiments, a third extreme value in the first voltammogram and a fourth extreme value in the second voltammogram with respectively associated voltages U₃, U₄ and current intensities I₃, I₄ are identified, wherein the first and second extreme value are assigned to a redox reaction and the third and fourth extreme value are assigned to an oxidation reaction of the electrochemical energy storage means. The curve profile of a voltammogram typically has at least two branches, wherein the first branch corresponds to positive values of the current intensity and the second branch corresponds to negative values of the current intensity. The first branch corresponds to the redox reaction within the electrochemical storage means. The second branch is assigned to an oxidation reaction within the electrochemical storage means.

By using the third and fourth extreme value and by comparing the third/fourth extreme value with the first/second extreme value, it is advantageously possible to determine the aging of the electrochemical storage means in a particularly precise manner. Some embodiments include forming the difference by the numerical difference (I₁+|I₃|)−(I₂−|I₄|). Some embodiments include forming the difference by the numerical quotient [I₂/(I₂+I₄]/[I₁(I₁+I₃)].

In some embodiments, a plurality of extreme values (first, second, third and fourth extreme value) are used for determining the aging. The aging of the electrochemical storage means can then be determined from the mentioned difference, for example by a calibration process. In the calibration process, the absolute relationship between the identified difference and the aging (SOH value) is set, with the result that the aging can be determined by the identification of the difference. In some embodiments, the difference is represented by the numerical quotient (I₁−I₃)/(I₂−I₄).

In some embodiments, the difference is formed by the angle Δα between a first and a second straight line, wherein the first straight line is set by the first and third extreme value and the second straight line is set by the second and fourth extreme value. In some embodiments, the aging SOH is represented by SOH=1−|Δα|/α₀, wherein α₀ is in the range of from 5 degrees to 15 degrees, e.g., α₀ of 10 degrees. In this case, Δα is also determined in degrees.

In some embodiments, a lithium-ion cell is used as the electrochemical storage means. Lithium-ion cells have particularly clear extreme values within the voltammograms of said lithium-ion cells. Said extreme values can then be detected easily and used for determining the aging of the lithium-ion cells.

In some embodiments, the first and/or second extreme value correlates to a peak value of the current intensity in the range of from 3.4 V to 3.7 V, in particular at 3.6 V. The extreme value at approximately 3.6 V is a redox reaction and hence the equilibrium voltage of the phase transition there results from or involves the intercalation/decalation of the lithium into/from NCA. This produces transitional potentials in order to force the redox reaction, which transitional potentials lead to the extreme values being shifted. For example, the level of the extreme values significantly decreases from the first voltammogram to the second voltammogram. The aging can then be assigned unambiguously from the change in the level (current intensity) of the extreme values.

In some embodiments, a value in the range of from 0.01 mV/s to 0.03 mV/s may be used as the voltage scan rate of the first and/or second cyclic voltammetry process. In some embodiments, voltammograms are thereby identified in relation to the aging of the electrochemical storage means. Said voltammograms show, in particular, clear extreme values, which can be used for determining the aging of the electrochemical storage means.

In some embodiments, an energy storage means of an aircraft, in particular of an electric aircraft, is used as the electrochemical storage means. The methods described herein make it possible to determine the aging independently of the operation of the electrochemical storage means. In other words, the aging of the electrochemical storage means can be detected during the operation thereof according to the intended application without disturbing or interrupting the operation. For example, electric aircraft typically have to be supplied with power by the electrochemical storage means constantly during the operation thereof in the air. This also, then, increases the operational safety of the aircraft. In some embodiments, the electrochemical storage means is provided for the driving of the electric aircraft. In other words, the electric aircraft comprises an electrochemical storage means, the aging of which is determined by means of the method according to the invention or one of the configurations thereof, for example during the flight operation of the electric aircraft. This can increase the operational safety of the electric aircraft.

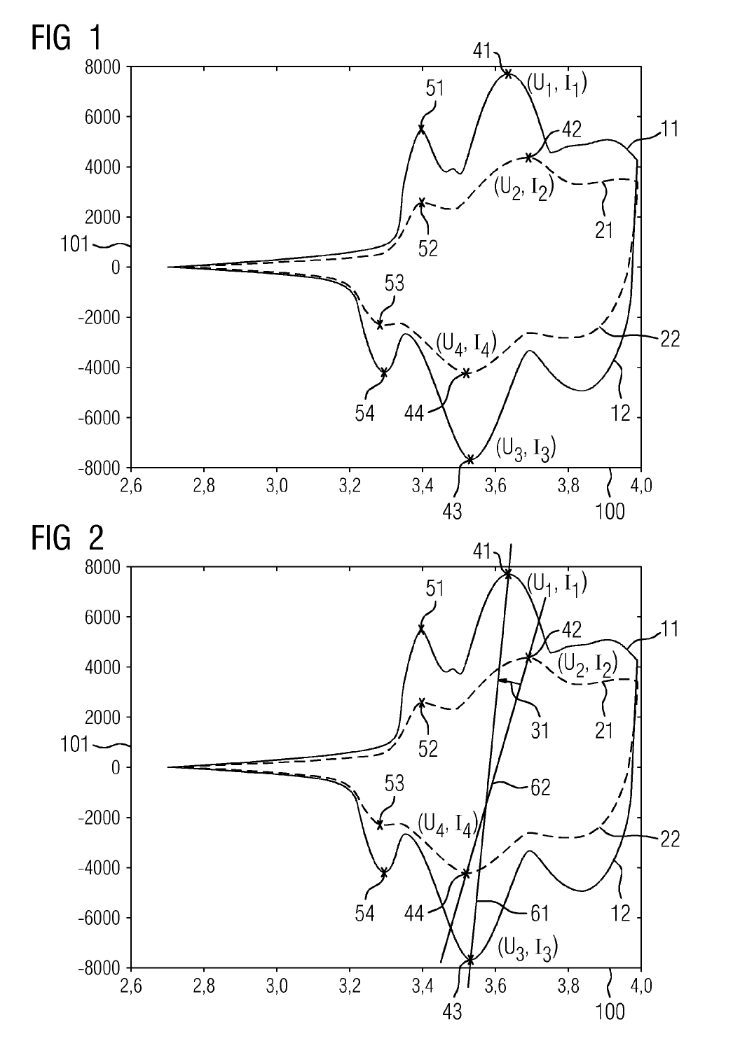

FIG. 1 shows a first voltammogram 11, 12 and a second voltammogram 21, 22. The first voltammogram 11, 12 is formed from a first branch 11 and a second branch 12. The second voltammogram 21, 22 is likewise formed from a first branch 21 and a second branch 22. The voltammograms 11, 12, 21, 22 have been identified by means of a voltage scan rate, for example at 0.01 mV/s. The present voltage at the electrochemical storage means is plotted on the abscissa 100 of the illustrated graph. The detected response of the electrochemical storage means to the presently applied voltage, which is given by the current intensity, is illustrated on the ordinate 101 of the illustrated graph.

The first voltammogram 11, 12 has been identified at an earlier time than the second voltammogram 21, 22. The difference between the first voltammogram 11, 12 and the second voltammogram 21, 22 is clear to see. The first voltammogram 11, 12 and the second voltammogram 21, 22 have a plurality of extreme values (peaks). In this case, a first extreme value 41 is present at approximately 3.6 V. A second extreme value 42 is shifted slightly to the right with respect to the first extreme value 41. The level (current intensity) of the second extreme value 42 is also reduced in comparison with the current intensity of the first extreme value 41. The aging of the electrochemical storage means can be determined from the shift, that is to say from the voltage difference between the first extreme value 41 and the second extreme value 42 and/or from the difference in level, that is to say from the difference of the current intensity of the first extreme value 41 and of the second extreme value 42.

The first branch 11 (redox branch) of the first voltammogram 11, corresponds to a redox reaction within the electrochemical storage means. The second branch 12 (oxidation branch) of the first voltammogram 11, 12 corresponds to an oxidation reaction within the electrochemical storage means. The first branch 21 of the second voltammogram 21, 22 corresponds analogously to a redox reaction and the second branch 22 of the second voltammogram 21, corresponds analogously to an oxidation reaction within the electrochemical storage means.

The first and the second extreme value 41, 42 are each located on the first branch 11, 21 (redox branch). A further third and fourth extreme value 43, 44 are located on the oxidation branch 12, 22 of the respective voltammogram 11, 12, 21, 22. The third and fourth extreme value 43, 44 can also be used analogously to the first and second extreme value 41, 42 for determining the aging of the electrochemical storage means. The voltammograms 11, 12, 21, 22 illustrated in FIG. 1 have further extreme values 51, 52, 53, 54, which can be used exclusively or additionally for determining the aging analogously to the first, second, third and fourth extreme value 41, 42, 43, 44. In some embodiments, mixed forms are used. For example, the aging may be determined by the change in the current intensity between the extreme values and the change in the voltages between the extreme values.

FIG. 2 shows similar voltammograms 11, 12, 21, 22 as already shown in FIG. 1. FIG. 2 illustrates how the aging of the electrochemical storage means can be determined from the determination of an angle Δα 31 between extreme values of the voltammograms 11, 12, 21, 22. In this case, FIG. 2 shows essentially the same elements as already shown in FIG. 1.

The first voltammogram 11, 12 has a first extreme value 41 and a third extreme value 43. The second voltammogram 21, 22 has a second extreme value 42 and a fourth extreme value 44. The first extreme value 41 and the third extreme value 43 define a first straight line 61, which has the angle 31 to a second straight line 62, which is defined by the second extreme value 42 and the fourth extreme value 44. The angle 31 represents a measure for the aging of the electrochemical storage means, with the result that the aging of the electrochemical storage means can be determined from the determination illustrated here of the angle 31 between the first and second straight line 61, 62.

Additional extreme values 51, 52, 53, 54 can also be used for determining the aging. In this case, the first straight line is then defined by the extreme values 51, 54 and the second straight line is defined by the extreme values 52, 53. An angle would also result here between the mentioned straight lines, which angle can be used exclusively or additionally for determining the aging of the electrochemical storage means.

The method for determining the aging illustrated in FIG. 1 can be combined with the method for determining the aging of the electrochemical storage means illustrated in FIG. 2. At least one pair of extreme values is thus used for determining the aging of the electrochemical storage means. Although the teachings herein have been illustrated and described in more detail by the exemplary embodiments, the invention is not limited by the disclosed examples, or other variations can be derived therefrom by a person skilled in the art without departing from the scope of protection of the invention.

What is claimed is:

1. A method for determining the aging of an electrochemical storage means, the method comprising:
recording a first voltammogram using a cyclic voltammetry process at a first time;
recording a second voltammogram using a further cyclic voltammetry process at a second time later relative to the first time;
identifying a first extreme value in the first voltammogram and a second extreme value in the second voltammogram, wherein a voltage (U₁, U₂) and a current intensity (I₁, I₂) are associated with each extreme value; and
determining the age of the electrochemical storage means based at least in part on a difference between the first and second extreme value.

2. The method as claimed in claim 1, wherein the difference comprises a numerical difference ΔU=U₁−U₂ of the voltages associated with the extreme values.

3. The method as claimed in claim 2, wherein determining the age depends on a formula SOH=1−|ΔU|/U₀, wherein SOH represents the age and U₀ is in the range of from 10 mV to 50 mV.

4. The method as claimed in claim 1, wherein the difference depends on a numerical difference ΔI=I₁−I₂ of the current intensities I₁, I₂ associated with the extreme values.

5. The method as claimed in claim 4, wherein determining the age depends on the formula SOH=1−|ΔI|I₀, wherein SOH represents the age and I₀ is in the range of from 100 mA to 500 mA.

6. The method as claimed in claim 1, further comprising identifying a third extreme value in the first voltammogram and a fourth extreme value in the second voltammogram with respectively associated voltages U₃, U₄ and current intensities I₃, I₄;
wherein the first and second extreme value are assigned to a redox reaction and the third and fourth extreme value are assigned to an oxidation reaction of the electrochemical energy storage means.

7. The method as claimed in claim 6, wherein the difference depends on a numerical difference (I₁+|I₃|)−(I₂−|I₄|).

8. The method as claimed in claim 6, wherein the difference depends on a numerical quotient [I₂/(I₂+I₄)]/[I₁/(I₁+I₃)].

9. The method as claimed in claim 6, wherein the difference depends on a numerical quotient (I₁−I₃)/(I₂−I₄).

10. The method as claimed in claim 6, wherein the difference is equivalent to an angle Δα between a first and a second straight line;
the first straight line passes through the first and third extreme value and the second straight line passes through the second and fourth extreme value.

11. The method as claimed in claim 10, wherein the age SOH is determined by SOH=1−|Δα|/α₀, wherein α₀ is in the range of from 5 degrees to 15 degrees.

12. The method as claimed in claim 1, wherein the electrochemical storage means comprises a lithium-ion cell.

13. The method as claimed in claim 12, wherein at least one of the first and the second extreme value is set as a peak value of current intensity in the range of from 3.4 V to 3.7 V.

14. The method as claimed claim 1, wherein a voltage scan rate is set to a value in the range of from 0.01 mV/s to 0.03 mV/s for at least one of the first and the second cyclic voltammetry process.

15. The method as claimed in claim 1, wherein the energy storage means comprises an energy battery for an aircraft.
